(19) United States
(12) Patent Application Publication
(10) Pub. No.: US 2015/0121701 A1
(43) Pub. Date: May 7, 2015

(54) Cold Plate with Pins

(71) Applicant: Wolverine Tube, Inc., Decatur, AL (US)

(72) Inventors: Sy-Jenq Loong, Madison, AL (US); Donald Lynn Smith, Danville, AL (US)

(73) Assignee: Wolverine Tube, Inc., Decatur, AL (US)

(21) Appl. No.: 14/596,876

(22) Filed: Jan. 14, 2015

Related U.S. Application Data
(63) Continuation of application No. 12/573,107, filed on Oct. 3, 2009, now abandoned.

(51) Int. Cl. B23P 15/26; H05K 7/20; B01D 8/00

(52) U.S. Cl. CPC B23P 15/26; B01D 8/00; H05K 7/20254
USPC 29/890.035

(57) ABSTRACT

A cold plate includes an enclosure with an inlet, an outlet, a base and a lid. The inlet and outlet are in fluid communication, so fluid can flow from the inlet though the enclosure to the outlet. The base is formed from a base plate, and the base plate includes an island facing into the enclosure. A plurality of pins extends from the island toward the lid. The pins can have a spiral shape, where the cross sectional profile of the pins change along the length of the pin.

### CROSS-REFERENCE TO RELATED APPLICATIONS

This application is a continuation of and claims the benefit of U.S. application Ser. No. 12/573,107 entitled “Cold Plate with Pins,” filed on Oct. 3, 2009, the contents of which are herein incorporated by reference in their entirety.

### BACKGROUND OF THE INVENTION

1. Field of the Invention

This invention relates to the production and use of a cold plate, which is used to transfer heat.

2. Description of the Related Art

Certain electronic devices generate heat as they operate, and this heat has to be removed or dissipated for the device to continue operating properly. Several techniques have been used to cool electronic equipment. Examples include fans, which are used to blow air over electronic equipment. This air serves to convectively cool the electronic equipment with normal ambient air. Other techniques that have been used include liquid cold plates. Liquid cold plates are plates with channels through which liquid flows. The electronic equipment is mounted in contact with a liquid cold plate and the heat generated by the electronic equipment is transferred to the coolant inside the plate. This can provide better cooling than the convective cooling provided by a fan with considerably less flow volume. It can also provide better temperature consistency with less acoustic noise.

Cold plates can be directly affixed to a heat-producing piece of electronic equipment, such as an electronic chip or an insulated gated bipolar transistor (IGBT). Typically, the cold plate includes an inlet and an outlet for liquid coolant flow. The liquid coolant absorbs the heat produced by the electronic equipment, and transfers the absorbed heat to the coolant which then flows out of the cold plate. Many cold plates provide cooling with a relatively low flow of liquid coolant. They can provide a degree of temperature consistency, minimal acoustic noise and the cooling power of liquid coolants.

Several factors impact the performance and desirability of cold plates, and different factors are important for different uses. Some important factors include cost of production and ease of producing relatively large quantities. Cooling efficiency should be high, and cold plates should be securely sealed so as to prevent any leak of liquid coolant onto the electronic equipment being cooled.

In some applications, the coolant may not be particularly clean, which can result in plugging of the cold plate. For example, a cold plate used in an automobile may utilize the anti-freeze liquid for cooling, and the anti-freeze can contain small particulates. In other applications, there may be a phase transfer within a cold plate to help facilitate cooling. It is also possible for a cold plate to be used for heating a component buy replacing the coolant with a heating fluid. One primary difference between a coolant and a heating fluid in one phase heat transfer is the temperature of a coolant is lower than the item being cooled, and the temperature of a heating fluid is higher than the item being cooled.

### BRIEF SUMMARY OF THE INVENTION

The current invention comprises a cold plate and a method of producing the cold plate. The cold plate has an enclosure with an inlet, an outlet, a base, and a lid. The base is formed from a base plate, and the base plate includes an island. A plurality of pins extends from the island into the enclosure, so a fluid can flow about the pins. The pins can have a spiral shape, where the cross sectional profile of the pins change along the pin length.

### BRIEF DESCRIPTION OF THE SEVERAL VIEWS OF THE DRAWINGS

FIG. 1 shows a cooling system using a cold plate.

FIG. 2 is an exploded view of one embodiment of a cold plate.

FIG. 3 is a cross sectional side view of one embodiment of a cold plate.

FIG. 4 is a perspective view of a base plate.

FIG. 5 is a perspective view of a base plate with a different pin pattern.

FIG. 6 is a partial cross sectional side view of two pins as part of a base plate.

FIG. 7 a side view of one pin.

FIG. 8 is a perspective view of one pin sectioned into four pieces.

FIG. 9 is a perspective view of a tool forming fins in a base plate.

FIG. 10 is a side cross sectional view of a tool forming fins in a base plate.

FIG. 11 is a side cross sectional view of a tool forming fins at a different angle in a base plate.

FIG. 12 is a perspective view of a tool forming a pin from a fin.

### DETAILED DESCRIPTION

Some electronic components are limited by the heat they produce. Cooling can help to increase the utilization of some of these components. Different cooling techniques are more appropriate for different equipment or different circumstances. One cooling method uses fans to blow air over an electronic component for convection cooling. This technique is simple and safe, but does not provide the cooling potential of some other techniques. The utilization of a liquid coolant can provide more efficient cooling, but many electronic components can malfunction when splashed with a liquid, so some can be cautious when using liquid cooling. Nevertheless, liquid cooling can increase the overall efficiency of some electronic components, as well as providing certain other benefits. Secondary benefits can include decreased acoustical noise and superior temperature consistency in the electronic component.

### Heat Transfer Fundamentals

This description will focus on single phase heat transfer. It is recognized that cold plates and other heat transfer devices can be used for two phase cooling, and the invention is not limited to single phase cooling, but this description focuses on single phase heat transfer for simplicity and clarity.

Air or other gases could be used as the cooling medium in a cold plate, but liquids are preferred. Liquid cooling is different than gas cooling for several reasons. For example, liquids are denser than gases so more thermal mass is available to absorb heat from the electronic equipment. Also, liquids generally have higher thermal conductivities so heat will transfer into and through the liquid more rapidly than heat will transfer into and through a gas. Furthermore, liquids tend to have a higher specific heat than gases so a set quantity of liquid will absorb and transfer more heat than a comparable amount of gas. Because of this, when electronic equipment is utilized which produces large amounts of heat, many manufacturers may choose liquid cooling devices.

Reducing resistance to heat flow improves the efficiency of a heat transfer device. Two significant forms of resistance to heat flow include resistance through one material and resistance across an interface between two separate components or parts. Resistance to heat flow through a single material is minimized if the material is a heat conductor, instead of a heat insulator. Metals are usually relatively good conductors, and they can be formed and shaped in many ways. Copper is a metal which readily conducts heat, and it is relatively malleable, so copper is often used in cold plates. However, other materials can also be used, such as aluminum, titanium, steel, gold, or even non-metallic materials like graphite or ceramics.

Another source of resistance to heat flow is at the interface between two components or parts. Typically, when heat flows from a first component to another component which contacts the first, there is resistance to heat flow between the two components. Forming a heat transfer device from one solid substrate can help improve heat transfer. If one were to produce one heat transfer component separately and then affix that component to another, there would be a resistance to heat flow at the joint between the two components. This is true even if the separate components were made from the same material, such as copper. Forming a heat transfer device from fewer components can improve heat transfer. When one piece is formed from another so there is no joint between the two, the pieces are said to be monolithic in this description.

Heat flow can also be improved by increasing the surface area where two different materials contact each other. When a liquid flows over a solid, heat is transferred between the two materials where the liquid contacts the solid. Increasing the surface area where the liquid contacts the solid is another way to decrease resistance to heat transfer, and increase the efficiency of a heat transfer device.

In some cases, liquids will flow across a solid in what is referred to as laminar flow. In laminar flow, the layer of liquid directly contacting the solid surface remains essentially stationary at the solid surface. The layer of liquid directly above that layer moves very gradually across the first layer. The next layer up moves a little more swiftly, etc., such that the highest flow rate will be at a point relatively far from the solid surface. The lowest flow rate, which is essentially zero, will be at the solid surface. Each different layer of liquid which is sliding over the adjacent layers provides its own resistance to heat flow. Therefore, if the liquid can be mixed during flow, the liquid directly contacting the solid surface can absorb heat from the solid surface and then be mixed with the entire body of cooling liquid to spread the absorbed heat into the liquid more rapidly.

Turbulent flow causes liquids to mix as they flow across a solid surface, as opposed to laminar flow. This tends to keep the liquid in contact with the solid surface cooler, which facilitates a faster transfer of heat from the solid surface to the liquid. Some things which tend to increase turbulent flow include faster flow rates, uneven surfaces, projections into a flowing liquid, and various obstructions that force a liquid to change path and flow another way. To maximize turbulence, one can include sharp bends, twisting edges, curved pillars, and any of a wide variety of flow obstructions that cause rapid change in the direction of flow of a liquid. Many structures which increase turbulence can also increase pressure drop across a cold plate. Increased pressure drop can lower the flow rate, so a balance must be observed to ensure efficient heat transfer. Obstructions which tend to increase the amount of fluid flow close to the solid surface also tends to increase heat transfer, because this reduces the thickness of any stagnant liquid layer at the solid liquid interface, and it also reduces the distance heated liquid has to travel to intermix with the main body of cooling liquid.

### Cold Plate Cooling System

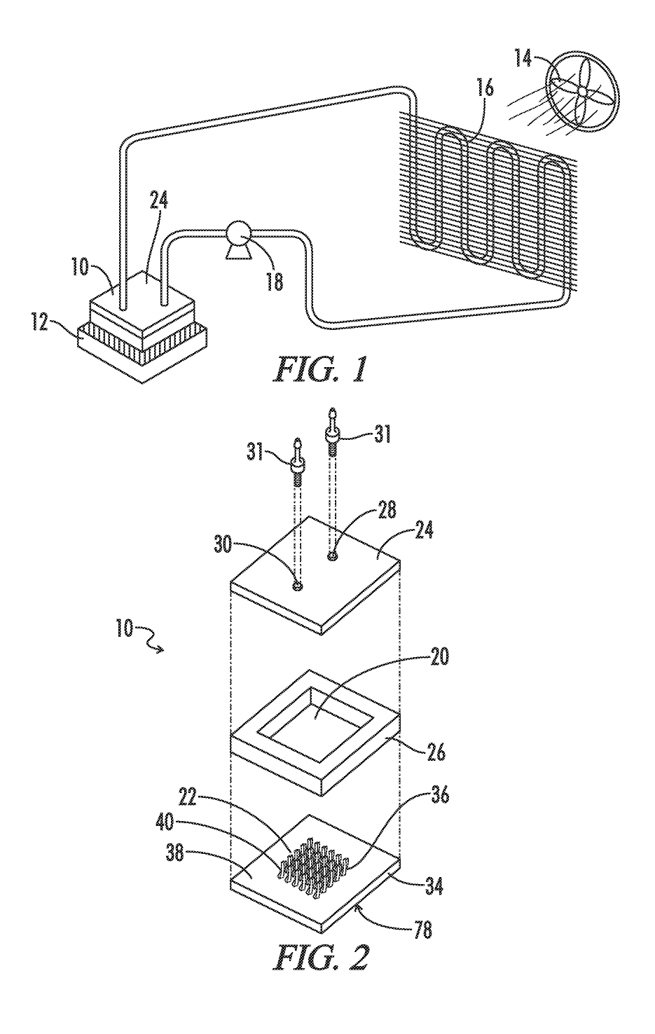

A cold plate 10 can be connected to an electronic component 12 or some other device to help cool the electronic component 12 or other device, as seen in FIG. 1. The cold plate 10 could also be used to heat a device in the same manner as cooling a device, but this description is directed towards cooling for simplicity and clarity. A cooling liquid, also referred to as coolant, is used to absorb heat from a heat source, such as an electronic component 12. After the coolant has absorbed the heat, it can be circulated to a different location where the coolant itself is cooled before being re-used for cooling. In one embodiment, a fan 14 blows cool air over a convective cooling device 16, similar to an automobile radiator, through which the coolant is circulated. A heat exchanger using facility water or other cooling systems could be used in place of the convective cooling device 16. It is also possible to simply move the heated fluid through a cooler area, such as by pumping the coolant through tubes exposed to air which is cooler than the coolant.

A pump 18 or other flow-inducing device can circulate the coolant through the cold plate 10. The cold plate 10 is affixed to an electronic component 12, such as with adhesive, sonic welding, brazing, soldering, diffusion bonding, or any other appropriate technique. Certain adhesives readily conduct heat, and can help minimize resistance to heat flow. Direct connection of the cold plate 10 to the electronic component 12 can minimize resistance to heat transfer. Use of a thermo-electric cooler between the cold plate 10 and the electronic component 12 can improve performance, but thermo-electric coolers are beyond this discussion. In one embodiment, the heat generated by the electronic component 12 is transferred to the coolant in the plate 10, and the coolant is then pumped to the convective cooling device 16 which is cooled with air from a fan 14. It is possible to connect a plurality of cold plates 10 or other heat exchanger devices in a single loop, so several electronic components 12 or other heat producing devices can be cooled with a single pump 18 and convective cooling device 16. For example, an automobile could use the water pump 18 to deliver antifreeze (a coolant) through the engine block to cool the engine, and also to deliver antifreeze to a water block 10 for cooling an electronic component 12.

Evaporative cooling can also be used, where a liquid is evaporated by the heat from the electronic component 12 or other heat source. Typically, the liquid is evaporated into a gas in an evaporator, and then the gas is re-condensed into a liquid in a condenser. It is also possible for the liquid to be evaporated and discharged from the system. A cold plate 10 can be used as an evaporator and/or a condenser. Many materials can be used as the coolant, including water, a water and glycol mixture, chloro fluoro carbons (CFCs), hydro chloro fluoro carbons (HCFCs), ammonia, brine solutions, oils, and many other materials.

### Cold Plate

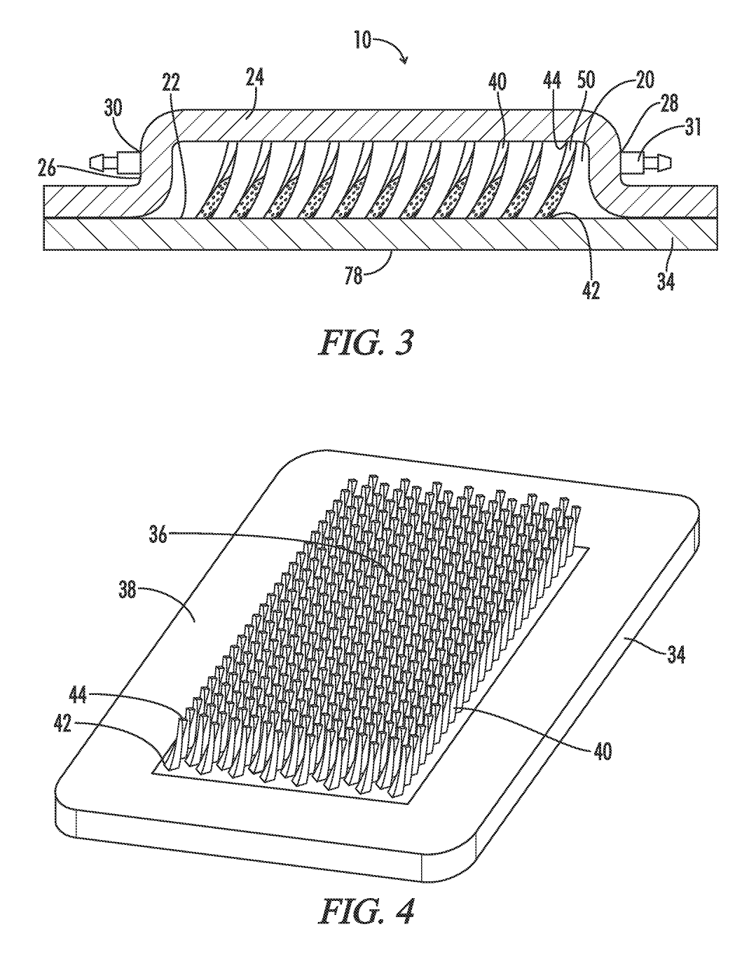

The cold plate 10 includes several structural components, as seen in FIGS. 2, 3, and 4, with continuing reference to FIG. 1. Coolant in the cold plate 10 flows through an enclosure 20, and the enclosure 20 has a base 22 and a lid 24. The enclosure 20 will also typically include side walls 26. The base 22 is at the bottom of the enclosure 10, and the lid 24 is at the top. The side walls 26 may be incorporated as part of a single structure used to make the lid 24, or the side walls 26 can be a separate structure, or the side walls may be a part of the base 20. It is also possible for the base 22 and lid 24 to gradually slope together, so there is no sharp demarcation between the side walls 26 and the base 22 and/or lid 24. The enclosure 20 can be almost any shape, so if the enclosure is round or cylindrical, the side walls 26 could be one continuous wall.

Coolant or other fluids enter and exit the enclosure 20 through an inlet 28 and an outlet 30. The inlet 28 and/or outlet 30 may penetrate the lid 24, a side wall 26, or the base 22, as long as the inlet 28 and outlet 30 allow for fluid to enter and exit the enclosure 20. The inlet 28 and outlet 30 are in fluid communication through the enclosure 20, so fluid enters the enclosure 20 through the inlet 28, travels through the enclosure 20, and then exits the enclosure 20 through the outlet 30. This direction of flow could also be reversed. It is also possible for there to be more than one inlet 28, and/or more than one outlet 28. A nozzle 31 or similar device can be connected to the cold plate 10 at the inlet 28 and/or outlet 30 to facilitate fluid flow.

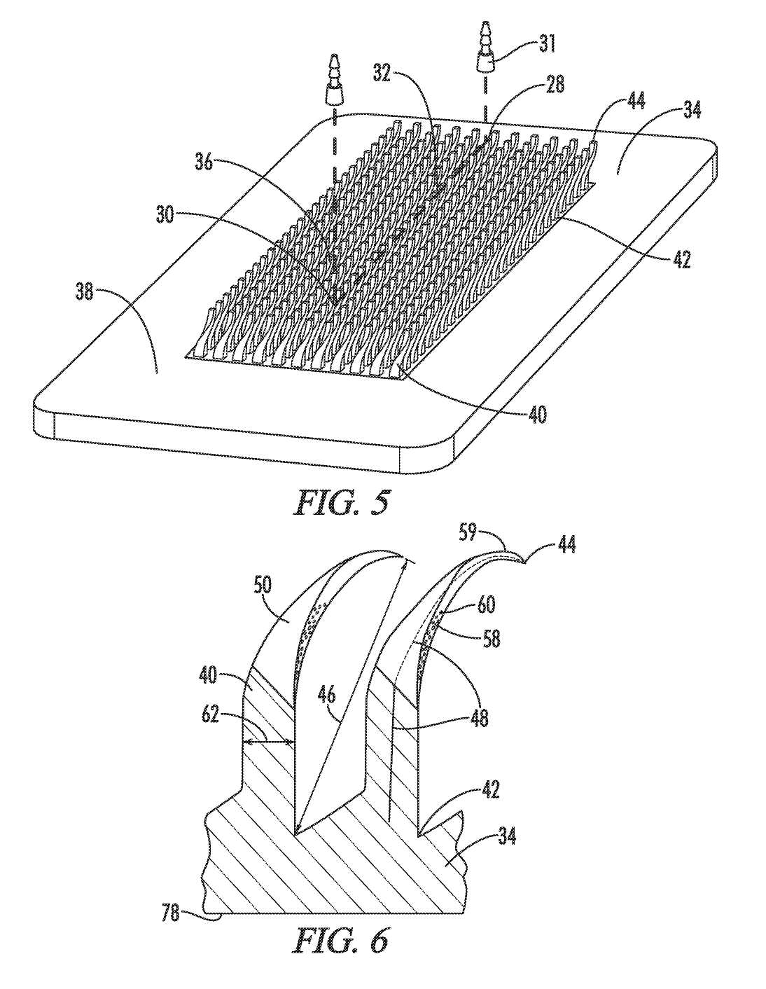

The positioning of the inlet 28 and outlet 28 influence the flow pattern through the enclosure 20. A flow line 32 is defined as a line straight between the inlet 28 and the outlet 30, as seen in FIG. 5, with continuing reference to FIGS. 1-4. In some embodiments, the flow pattern will tend to follow the flow line 32, but some structures within the enclosure 20 can alter the flow pattern. The angle at which the inlet 28 and/or outlet 30 penetrate into the enclosure 20 can also influence the flow pattern, because the inlet 28 can serve as a jet to direct flow, and the outlet can serve as a drain to direct flow. The location of the inlet 28 and/or outlet 30 can also influence the flow pattern, and this can be utilized with the angle at which the inlet 28 and/or outlet 30 penetrate the enclosure 20 to establish a more desirable flow pattern. In some embodiments, a flow pattern which covers most of the base 22 is desired to maximize the area being cooled by flowing fluid.

The base 22 of the enclosure 20 is formed from a base plate 34. The base plate 34 includes an island 36, which is on the side of the base plate 34 facing into the enclosure 20. In some embodiments, a base plate back side 78, or the side of the base plate 34 opposite the island 36, is attached to the electronic component 12 or other heat producing device. It is also possible to attach a different part of the cold plate 10 to a heat producing device, if desired.

The base plate 34 can include an attachment area 38 around the island 36 for attaching side walls 26 and/or a lid 24. The connection of the base plate 34 to the lid 24 or side walls 26 should be water tight, to prevent the leakage of liquids (if the cooling fluid is a liquid). A smooth surface for the attachment area 38 can facilitate a water tight connection, but other surfaces may be useful as well. The attachment area 38 could include a groove with a matching lip on the lid 24 or side wall 26, or a roughed surface for use with an adhesive, or any of a wide variety of other options. In some embodiments, the lid 24 and/or side walls 26 slide completely around the base plate 34, so the attachment area 38 can be on a sideways facing surface of the base plate 34 which is perpendicular to the surface of the island 36. In other embodiments, the attachment area 38 can be raised up so a flat lid 24 can complete the enclosure 20. A wide variety of design options can be used for the attachment area 38.

A plurality of pins 40 extend from the island 36 upward toward the lid 24. The pins 40 can extend all the way to the lid 24, so the pins actually touch the lid 24, or the pins 40 can extend to a point short of the lid 24, so there is a gap between the pins 40 and the lid 24. The pins 40 in the cold plate 10 are arranged in some pattern. The pattern can be random, or the pattern can be ordered. In one embodiment, the pins 40 are aligned along lines parallel with the flow line 32, as shown in FIG. 5. This pattern is referred to as the aligned pattern. Having the pins 40 aligned with the flow line 32 tends to result in the coolant flowing between different rows of pins 40. This flow can help to reduce pressure drop in the cold plate 10. The spiral of the pins 40 in the aligned pattern can provide a cold plate 10 with some similarities to a cold plate 10 with a wavy fin design. In an alternate embodiment, the pins 10 are aligned in rows which cross the flow line 32, as shown in FIG. 4. This pattern is referred to as the staggered pattern. The rows of pins 10 can be set at almost any angle to the flow line 32, such as a forty five degree angle, a thirty degree angle, or essentially any other angle. In the staggered pattern, the fluid is forced to flow around the staggered pins, so the fluid can not flow in a straight line parallel with the flow line 32. This tends to cause a zig zag flow pattern, which tends to increase turbulence and also increase pressure drop across the cold plate 10.

### Pin Shape

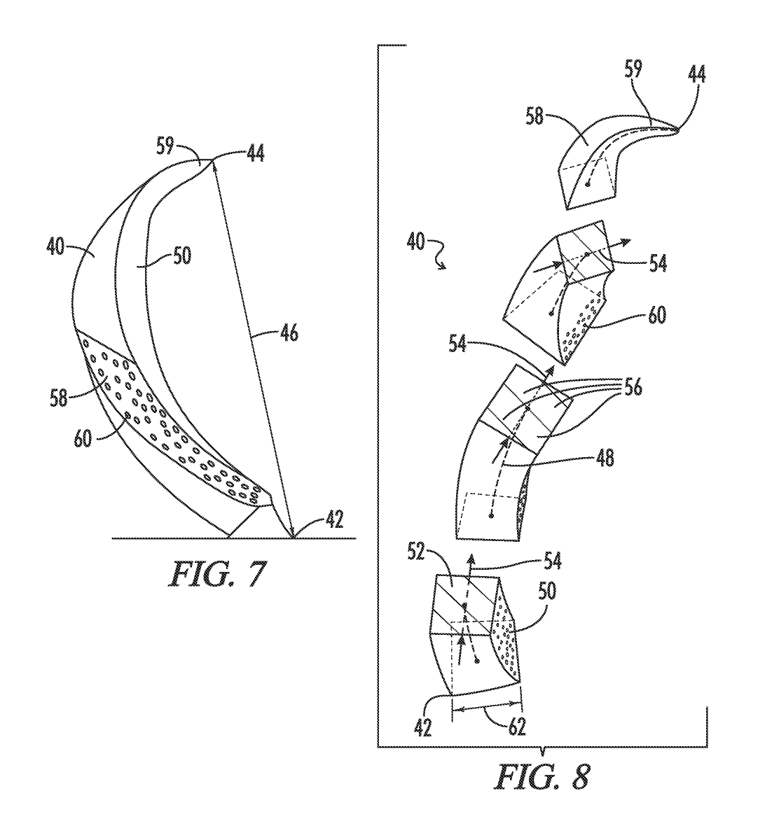

The pins 40 have a shape, and the shape can affect the heat transfer efficiency of the cold plate 10, as seen in FIGS. 6, 7, and 8, with continuing reference to FIGS. 1-5. The pins 40 have a pin bottom 42, which is where the pin 40 attaches to the island 36 of the base plate 34, and the pins 40 have a top 44 at the opposite end of the pin 40 from the pin bottom 42. So, the top 44 is generally the portion of the pin 40 closest to the lid 24. A pin length 46 is measured from the pin bottom 42 to the pin top 44, and a pin axis 48 runs down the center portion of the pin 40. The axis 48 runs through the center of the pin 40, so the axis 48 would be at the center point of any cross section of the pin 40. The pin 40 also includes a side surface 50, which is the outer surface of the pin 40 on the side, running from the bottom 42 to the top 44.

Each pin 40 has a cross sectional profile 52, where a cross section is perpendicular to the axis 48. The cross sectional profile 52 is the shape of the cross section. This cross sectional profile 52 can be many different shapes, but in some embodiments it is generally a quadrilateral. Each cross sectional profile 52 also has a cross sectional orientation 54, which refers to the way the cross section is facing. A quadrilateral, or any other shape, does not have a clear, set front end, but any side or point along the perimeter of the cross section can be selected as a point of reference for the cross sectional orientation 54. The cross sectional profile 52 can change along the pin length 46, so the size or general shape is not necessarily fixed and constant for the entire length 46 of the pin 40. The cross section also has a cross sectional area 56, which is the area of the cross section. The cross sectional area 56 can also vary along the length 46 of the pin 40, so the pin 40 can get fatter or skinnier at different points along the pin length 46.

The pins 40 of the current invention have some specific structural aspects. In one embodiment, the pins 40 have a spiral shape. The cross sectional orientation 54 changes along the pin length 46, and the point of reference used for the cross sectional orientation 54 tends to consistently move in the same direction from the pin bottom 42 to the top 44. The cross sectional orientation 54 may not change along the entire pin length 46, but it does change along at least a portion of the pin length 46. This gives a spiral appearance to at least a portion of the pin 40. In other embodiments, the point of reference may move in one direction for one portion of the pin 40, move another direction for a different portion of the pin 40, and may possible not move for yet a different portion of the pin 40. A polyhedral shape, such as a quadrilateral, results in edges along the pin side surface 50. The varying cross sectional orientation 54 along the pin length 46 results in the edges changing position along the pin length 46. This variation in the edges can increase turbulence in fluids flowing around the pin 40, and may therefore improve the efficiency of the cold plate 10. The incline angle of the pin 40 can also be manipulated by presetting an angle of a cutting tool used in the formation of the pin 40, as discussed in greater detail below.

The pin 40 may also have a bend in some embodiments. The pin 40 is said to be bent when the axis 48 bends along the pin length 46. Because of possible changes in the cross sectional profile 52 of the pin along the pin length 46, it is possible for one side of a pin 40 to appear relatively straight, and the other side to appear bent, but the axis 48 of the pin 40 still bends along the pin length 46. In some embodiments, the bent shape of the pin 40 appears similar to a banana, however the appearance of the pin 40 varies in different embodiments. In some embodiments, there is a “fish hook” 59 present near the pin top 44, where the fish hook 59 is a more sharply bent portion of the pin 40; however in other embodiments the fish hook shape is not present. The fish hook 59 looks somewhat like the stem of a banana. The bent shape of the pin 40 presents an obstacle with a varying shape for fluid to flow around, which may increase turbulence in the cold plate 10. The bent shape can direct fluid flow up and/or down to further vary the fluid flow pattern, and thereby possibly increase turbulence. Fluid flow directed downward toward the base plate 34 comes nearer to what may be the hottest part of the cold plate 10. This increased flow nearer to the pin bottom 42 may increase heat transfer. There can be a larger temperature differential between the solid material of the cold plate 10 near the pin bottom 42 and mixed coolant flowing nearby, and an increased temperature differential can increase the overall cold plate efficiency.

In other embodiments, the pin 40 can have at least two different textures 58 on the side surface 50. At least one of these textures 58 includes dimples 60, and can appear somewhat like an orange peel. The dimples 60 are indentations extending into the pin 40 from the surface for at least some distance. The different textures 58 can be on different faces of the quadrilateral or polyhedral shape of the pin 40. In some embodiments, the side surface 50 will include at least three different textures, and there can be two different textures 58 along one face of the polyhedral shape of the pin 40. The different surface textures 58 provide additional structure which can cause turbulence and help increase heat transfer. The dimples 60 provide varying surface structure which does tend to increase turbulence in fluid flowing past the pin 10, and a change in texture may also cause turbulence.

The pin 40 may also have a varying thickness along the pin length 46 in some embodiments. There may be a taper to the pin 40 at the pin bottom 42, so the thickness of the pin 40 is decreasing closer to the pin bottom 42. Stated more technically, the cross sectional area 56 can increase with an increasing distance from the pin bottom 42 for a least a portion of the pin 40. This is consistent with the banana shape of the pin 40, because a banana tends to taper near the end of the banana opposite the stem. This can result in a pin 40 which is thicker near the middle or top 44 than at the pin bottom 42. Providing more room for fluid to flow near the pin bottom 42 than higher up on the pin 40 urges fluid to flow closer to pin bottom 42 and the base plate 34. The base plate 34 can be connected to the heat producing item to be cooled, so increased fluid flow near the base plate 34 can increase heat transfer efficiency. In other embodiments, the pin 40 does not become thicker further from the bottom 42, so any taper is present is a thinning of the pin 40 progressing from the bottom 42 to the top 44.

In some embodiments, the pin 40 can be monolithic with the base plate 34, which means there is no joint between the pin 40 and base plate 34. This can be accomplished by forming the pin 40 directly from the base plate 34, instead of forming the pin 40 separately and then securing the pin 40 to the base plate 34 in some manner. Having the pin 40 monolithic with the base plate 34 can increase heat transfer by reducing the resistance to heat flow from the base plate 34 up the pin 40. As heat flows up the pin 40, fluid flows past the pin 40, absorbs the heat from the pin 40, and increases the overall heat transfer efficiency of the cold plate 10. The pins 40 provide additional surface area for heat transfer from the base plate 34, and a low resistance to heat flow between the base plate 34 and the pins 40 increases overall heat transfer efficiency.

The pins 40 can include an aspect ratio of twenty to one in some embodiments, where the pin length 46 is twenty times the distance across the pin 40, or pin width 62. Heat transfer is increased by increasing the aspect ratio, because a longer pin 40 with the same width 62 tends to have more surface area, and increasing surface area tends to increase heat transfer efficiency.

The various aspects of the pin shape described above can be present in the pins 40 in isolation, or any combination. This includes the quadrilateral cross section, the spiral shape, the bent shape, the plurality of textures, the taper shape, the monolithic connection to the base plate, the incline angle, and the aspect ratio. Each pin 40 may include only one of these structures, or any combination of the structures, depending on manufacturing techniques and heat transfer properties desired, amongst other factors.

### Production Method of the Base Plate

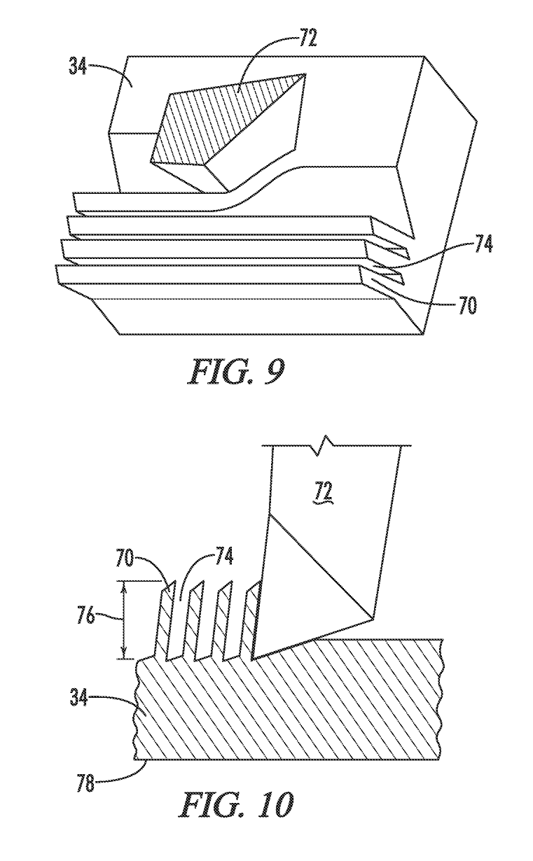

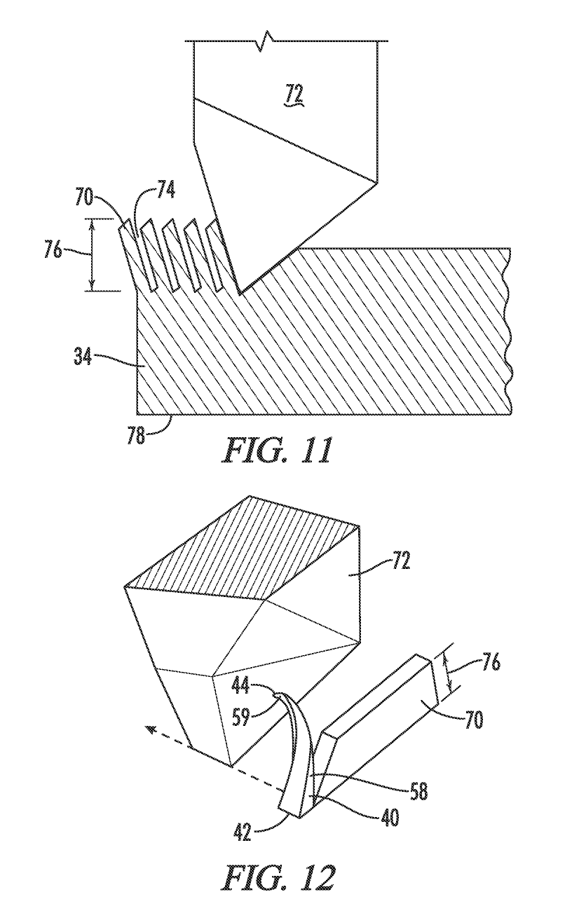

The current invention also includes a method of producing the cold plate 10, as seen in FIGS. 9-12, with continuing reference to FIGS. 1-8. The cold plate 10 is constructed by preparing a base plate 34, and attaching a lid 24 to the base plate 34. There can be other structures included as well, such as separate side walls 26. The lid 24 is attached to the base plate 34 such that there is an enclosure 20 positioned between the lid 24 and base plate 34. Standard production techniques can be used to produce the lid 24 and side walls 26. This includes stamping, cutting, casting, metal injection molding, machining and other techniques. The lid 24 and base plate 34 can also be joined by many standard techniques, such as brazing, welding, soldering, gluing, and other connection methods.

The production of the base plate 34 requires additional steps. The pins 40 are produced by first slicing fins 70 into the base plate 34, and then performing a second set of slices across the fins 70. The second set of slices essentially cross cut the fins, and this cross cutting produces the pins 40. One process used to slice the base plate 34 is called micro deformation technology (MDT), and it is described in U.S. Pat. No. 5,775,187, issued Jul. 7, 1998, which is hereby incorporated in full into this description. In this process, a base plate 34 is sliced with a tool 72 without removing material from the base plate 34. The MDT process is different than a saw or router, which removes material as cuts are made, and is more similar to the cutting of meat with a knife.

The slicing of the base plate 34 is done with the tool 72. As the tool 72 contacts the material of the base plate 34, a fin 70 is cut from the main block of material. This forms a channel 74 between adjacent fins 70, and can be done without removing material from the base plate 34. Preferably, there are no shavings produced in the formation of the fins 70. The tool 72 cuts fins 70 in to the base plate 34, and the space produced as the tool 72 passes through the base plate 34 material deforms and forces material in the fins 70 upwards. This cutting and deformation of the base plate 34 material causes the fins 70 to rise to a fin height 76 which is higher than the original base plate 34. The MDT cutting tool design, the depth of cutting, the width of the fins 70 and the channel 74 are factors which affect the fin height 76. This process is repeated until a bed of fins 70 has been produced.

The pins 40 are made by slicing across the fins 70. The second set of slices can also uses the MDT method, and raises the pins 40 to a length 46 greater than the fin height 76. As the slices are made, no material is removed from the base plate 34, so the moved material is instead directed into the remaining pin 40 or fin 70. This causes the remaining pin 40 or fin 70 raise to a height higher than the material from which the pin 40 or fin 70 was cut. The second set of slices can be made at an angle other than ninety degrees to the fins 70, but it has been found that the pin length 46 tends to vary when angles other than about ninety degrees are used. A cold plate 10 can be made with varying pin lengths 46 if desired, or the pin lengths 46 can be kept more consistent by making the second set of slices at about ninety degrees to the fins 70. In an alternate embodiment, the fins 70 are made without using the MDT process, and the pins 40 are then formed from the fins 70 using the MDT process. In another alternate embodiment, the fins 70 are made using the MDT process, and the pins 40 are then formed from the fins 70 using a conventional cutting process. This can generate a non-spiral structure of pins 40.

The technique of cross slicing the base plate 34 to produce the pins 40 contributes to the final shape of the pins 40. The first slice makes a fin 70 with two flat sides, and the second slice tends to make a pin 40 with two more flat sides, for a total of four relatively flat sides. The four relatively flat sides produce the quadrilateral cross sectional profile 52 for the pin 40. The quadrilateral cross sectional profile 52 provides edges between different side surfaces 50 which tend to increase turbulence in fluid flowing over those edges. Additionally, the slicing of the pins 40 from the base plate 34 results in the pins 40 being monolithic with the base plate 34, which improves heat transfer as discussed above. Additionally, the incline angle of the pin 40 and/or the fin 70 can be manipulated by the angle of the tool 72 as the slices are made. A modification of the incline angle of the fin 70 can change the incline angle of the pin 40.

The cutting action of the tool 72 on the material of the base plate 34 provides different textures to the material as it is cut. The surface which is cut and pushed up to form a fin 70 or pin 40 takes the texture of the cutting surface of the tool 72, which can be very smooth. The base plate surface on the opposite side of the tool simply has material cut away from it, and this tends to produce an orange peel texture 58, or a texture including a plurality of dimples 60. This results in the two surfaces facing each other across a channel 74 having different textures 58. The original surface texture 58 of the base plate 34 before any slices are made also remains on a portion of the pin 40. The original base plate surface is cut and lifted up in the fin 70, and then it is cut and lifted again in the second set of slices to form the pin 40. This surface texture 58 remains on a portion of the pin 40, which can provide a third texture 58 on the pin. The different textures 58 on the pin side surfaces 50 can increase turbulence by providing changes in the fluid flow pattern. The dimples 60 in particular tend to cause swirls, mixing, and turbulence more so than a smooth surface.

Slicing the pins 40 from fins 70 provides the bent shape of the pins 40, and can also provide the spiral shape of the pins 70. The fins 40 are free standing, so the cutting action of the tool 72 tends to bend the pin 40 over as it is cut. The fin 70 is more stable near the pin bottom 42, because this portion is attached to the base plate 34. The higher portions of the fin 70 do not have the support of the lower portions, and these higher portions tend to be bent over as the pin 40 is cut and formed. The tool 72 is only cutting on one side of the pin 40 as it is formed, so the bending force is only applied to one side of the pin 40. Because the bending force is only applied to one side of the pin 40, part of the bending force can serve to twist the pin 40, resulting in a spiral effect. The bent and spiral shaped pin 40 may increase turbulent flow and urge flow closer to the base plate 34, which can increase heat transfer efficiency as discussed above. One method which can help keep the flow path of the cold plate 10 more fully open is to slice the fins 70 in essentially a perpendicular direction to the final flow line 32, and then make the secondary slice to form the pins 40 essentially parallel to the flow line 32.

The taper and banana shape of the pin 40 can also result from the slicing of the MDT method. As a cut is made, the newly formed fin 70 or pin 40 is pushed upward to accommodate the material moved by the cutting action. The material near the pin bottom 42 is pushed up into the body of the pin 40, and can result in a thicker central portion of the pin 40. This thicker central portion provides the tapered shape of the pin bottom 42, and can also provide an opposite tapered shape near the pin top 44. The tool 72 can also catch the top portion of the fin 70 as it passes, and more readily mold this thinner material such that the fish hook 59 is formed. The fish hook 59 can be eliminated by trimming off the tip of the fin 70 prior to the second cutting process, if desired, or the fish hook 59 can be left in place. This fin trimming process also helps to control the final pin length 46.

The dual cross slicing to first form the fins 70, and then to form the pins 40, pushed material into the pin 40. This technique has been used to produce aspect ratios of twenty to one, as described above. The slices with the tool 72 can be done using known techniques with a wide variety of machines, including but not limited to a milling machine, a shaper, or even a lathe. The slicing of a base plate 34 can provide an efficient, relatively low cost method of producing pins 40 for a cold plate 10.

### Production Method of the Cold Plate

After an island 36 of pins 40 are formed, the base plate 34 can be prepared for assembly into a cold plate 10. The lid 24 is attached to the base plate 34, perhaps through a side wall 26 piece, to form the enclosure 20. An inlet 28 and an outlet 30 penetrate into the enclosure 20 to provide access for a coolant or other fluid. The inlet 28 and outlet 30 can be made before the base plate 34 and lid 24 are assembled, or after. Nozzles 31 can be attached to the inlet 28 and/or outlet 30 to facilitate fluid flow, and the shape of the inlet 28 and outlet 30 can vary. For example, the inlet 28 and outlet 30 can be a round hole, a square hole, a manifold covering the entire side of the cold plate 10, or any of a wide variety of other shapes. The inlet 28 and outlet 30 can be drilled, stamped, cut, or produced in a number of known techniques.

To prepare the base plate 34 to receive the lid 24 or side wall 26, an attachment area 38 is made. The attachment area 38 can be made in several different ways. In one embodiment, the entire upper surface of the base plate 34 is formed into pins 40, and the side surface of the base plate 34 is used as an attachment area 38. In an alternate embodiment, the attachment area 38 is formed on the outer edges of the upper surface of the base plate 34, with the island 36 of pins 40 positioned inside of the attachment area 38. In one embodiment, the attachment area 38 can be formed by machining after the entire upper surface of the base plate 34 is formed into pins 40. In an alternate embodiment, the attachment area 38 is machined to a lower level than the island 36 prior to forming the pins 40, and the slices of the tool 72 are set to pass over the attachment area 38. In this way, the island 36 of pins 40 is formed inside the attachment area 38 without disrupting the surface of the attachment area 38. A wide variety of other options using known techniques can also be used to produce the attachment area 38. The attachment area 38 can take many forms, depending on the type of attachment to be made, as discussed above.

The alignment of the pins 40 in the cold plate 10 can vary, including an aligned pattern or a staggered pattern. For a rectangular cold plate 10, the aligned pattern can be made by slicing the fins 70 and pins 40 in slices perpendicular to the edge of a rectangular base plate 34. The cold plate 10 is then constructed and with the inlet 28 and outlet 30 centered along one edge of the base plate 34. The staggered pin pattern can be made with the same base plate 34 as used for the aligned pattern, where the corners of the base plate 34 are removed to produce new edges. These new edges are no longer in line with the pins 40 sliced into the base plate, and the cold plate 10 can be constructed as before. In an alternative embodiment, the staggered pin pattern can be made by slicing the fins 70 and pins 40 at an angle to the edge of the base plate 34. The cross slices for the fins 70 and pins 40 can still be at ninety degrees, but the resulting pin pattern is not in rows parallel and perpendicular to the edges of the base plate 34. Other methods and techniques can also be used to produce different patterns of pins 40.

The back side 78 of the base plate 34, which is opposite the pins 40, may need to be very flat to make a good thermal connection with the electronic component 12 or other item to be cooled. It may be desirable to take steps to flatten the base plate back side 78 before the cold plate 10 is used. This back side 78 can be flattened in several ways, and it can be flattened before or after the pins 40 are formed. In some embodiments, the back side 78 is flattened after the pins 40 are formed to correct any warp or bending which may have occurred as the pins 40 were formed. Known techniques can be used to produce a flat back side 78 of the base plate 34. In embodiments where the back side 78 of the base plate 34 is flattened after the pins 40 are formed, measures can be taken to prevent damage to the pins 40. This can include a jig to suspend the pins 40 while machining the back side 78 of the base plate 34, and/or a vacuum system may be employed to hold the base plate 34 for subsequent flattening.

### Dimensions, Use, and Example

The cold plate 10 can be used for many different purposes. Different designs are better suited to different purposes. For example, if the cold plate 10 is used in motor vehicle with engine coolant fluid, the cold plate 10 should be designed to withstand some particulates in the coolant. If the cold plate 10 is used in a computer with a very clean, filtered coolant, particulate concerns are not as important. The dimensions discussed below can be used with a coolant having particulates up to one millimeter in diameter.

In one embodiment of the cold plate 10, the enclosure 20 is sized so the pins 40 essentially contact the lid 24. The pins 40 are approximately five millimeters high and approximately one millimeter wide. The gap between neighboring pins 40 is approximately one millimeter, and the total cold plate size is approximately fifteen centimeters by fifteen centimeters.

The performance of three different cold plates 10 was modeled with a computer simulation. In the model, the first cold plate 10 include fins 70, the second cold plate 10 included pins 40 with an aligned pattern, and the third cold plate 10 included pins 40 with a staggered pattern. The pins 40 in the model include spirals and bends as described in this description.

In each of the three computer models, the coolant was ethylene glycol with a density of 1,027 kilograms per cubic meter (kg/m³), a dynamic viscosity of 0.00169 Pascal seconds (Pa*s), a specific heat of 3,300 joules/kilogram degree Kelvin (J/(kg*K)), and a thermal conductivity of 0.388 watts per meter degree Kelvin (W/(m*K)). The flow rate of the coolant through the cold plates 10 was five liters per minute (1/min), and the temperature of the coolant at the inlet 28 was twenty degrees centigrade (C). The heat source was three components generating one hundred sixty six watts (w) each, where each component has an area of fifteen by twelve millimeters (mm), for a total of approximately five hundred watts (w). The coolant flowed sequentially past each heat source.

The specific structure of the cold plates 10 was used in the computer model, and each cold plate 10 had the same length and width. The first cold plate 10 with fins 70 had ten fins per inch, with a fin thickness of one millimeter, a fin height of four point seven millimeters, and a gap between neighboring fins 70 of one millimeter. The second cold plate 10 with pins 40 in an aligned pattern had ten pins per inch, a pin thickness of one millimeter, a pin height of four point seven millimeters, and a gap between neighboring pins 40 of one millimeter. The third cold plate 10 with pins 40 in a staggered patter had ten pins per inch, a pin thickness of one millimeter, a pin height of four point seven millimeters, and a gap between neighboring pins 40 of one millimeter.

The model calculated the steady state temperature of each heat source. The coolant flowed past the three heat sources sequentially, so each heat source increased the temperature of the coolant as the coolant passed. Therefore, the first heat source, which was closest to the inlet 28, was cooled by the coldest coolant, and reached the coldest steady state temperature. The third heat source was cooled by coolant that had been warmed by the first two heat sources, so the third heat source reached the hottest steady state temperature. The second heat source was between the first and third heat sources, so the second heat source reached a steady state temperature between that of the first and third heat source. The steady state temperatures are listed in the table below in degrees centigrade. The computer model also calculated the pressure drop across each cold plate 10, and that value is listed below in pounds per square inch.

| | First Heat | Second Heat | Third Heat | Pressure |
|---|---|---|---|---|
| Cold Plate Number | Source | Source | Source | Drop |
| First (fins) | 40.9 | 43.2 | 43.5 | 1.53 |
| Second (aligned pins) | 35.3 | 37.8 | 38.9 | 1.85 |
| Third (staggered pins) | 31.4 | 33.8 | 34.8 | 2.21 |

This model shows the use of pins 40 can increase heat transfer efficiency over the use of fins 70. Developing a better pin 40 may increase the heat transfer efficiency even more.

While the invention has been described with respect to a limited number of embodiments, those skilled in the art, having the benefit of this disclosure, will appreciate that other embodiments can be devised which do not depart from the scope of the invention as disclosed here.

What is claimed is:

1. A method of producing a cold plate comprising:
slicing a base plate to form a plurality of fins monolithic with the base plate;
cross-slicing the base plate after the fins are formed to form a plurality of pins monolithic with the base plate;
attaching a cover to the base plate such that the plurality of pins are contained within an enclosure between the cover and the base plate; and
forming an inlet and an outlet to the enclosure.

2. The method of claim 1 where the base plate is sliced such that the pins spiral between a pin bottom and a pin top.

3. The method of claim 1 where the base plate is sliced such that a pin axis bends along a length of the pin.

4. The method of claim 1 where the base plate is sliced without removing material so the fins elevate from the base plate.

5. The method of claim 1 where the base plate is cross-sliced without removing material so the pins elevate from the fins.

6. The method of claim 1 where the base plate is sliced with a tool to produce at least two textures on a side surface of the pins.

7. The method of claim 6 where at least one texture of the side surface includes a plurality of dimples.

8. The method of claim 7 where the side surface of a first pin has a dimpled surface and the side surface of a facing adjacent second pin has a non-dimpled surface.

9. The method of claim 1 where the pin comprises a cross sectional area, and where for at least a portion of the pin the cross sectional area increases with increased distance from a pin bottom.

10. The method of claim 1 where the pin has a width essentially perpendicular to the length, and the pin has an aspect ratio of at least ten to one, where the aspect ratio is the ratio of the pin length to the pin width.

11. The method of claim 1 where the pin has a bottom, a top, and an axis, and where the axis bends between the bottom and the top.

12. The method of claim 3, where the step of cross-slicing the base plate after the fins are formed to form the pins also forms a fish hook portion at a top of the pin, wherein the fish hook portion is more sharply bent than the remainder of the pin.

13. The method of claim 2, further comprising milling the pin tops to form a flat surface at the top of the pins.

14. A method of producing a cold plate comprising:
slicing a base plate to form a plurality of fins monolithic with the base plate;
cross-slicing the base plate after the fins are formed to form a plurality of pins monolithic with the base plate, where each pin includes a length and an axis, and where the axis bends along the pin length, and where each pin has a cross sectional profile with an orientation, and where the orientation changes along the length of the pin such that the pin twists for at least a portion of the length of the pin, and where the pins are monolithic with the base plate;
attaching a cover to the base plate such that the plurality of pins are contained within an enclosure between the cover and the base plate; and
forming an inlet and an outlet to the enclosure.

15. The method of claim 14, where the step of cross-slicing the base plate after the fins are formed to form the pins also forms a fish hook portion at a top of the pin, wherein the fish hook portion is more sharply bent than the remainder of the pin.

16. The method of claim 14, further comprising milling the pin tops to form a flat surface at the top of the pins.

17. The method of claim 14 where the base plate is sliced without removing material so the fins elevate from the base plate.

18. The method of claim 17 where the base plate is cross-sliced without removing material so the pins elevate from the fins.
